(19) United States
(12) Patent Application Publication
(10) Pub. No.: US 2016/0268538 A1
(43) Pub. Date: Sep. 15, 2016

(54) LIGHT EMITTING DEVICE

(71) Applicant: OLEDWORKS GMBH, Aachen (DE)

(72) Inventors: Holger Schwab, Aachen (DE); Manfred Ruske, Kerpen (DE)

(73) Assignee: OLEDWorks GmbH, Aachen (DE)

(21) Appl. No.: 15/033,756

(22) PCT Filed: Nov. 4, 2014
(86) PCT No.: PCT/EP2014/073616

§ 371 Date: May 2, 2016

(30) Foreign Application Priority Data
Nov. 5, 2013 (EP) 13191601.7

(51) Int. Cl. H01L 51/52

(52) U.S. Cl. CPC H01L 51/5212; H01L 51/5268; H01L 51/5275; H01L 51/5231; H01L 2251/558

(57) ABSTRACT

The invention relates to a light emitting device (1) comprising a substrate (5), a transparent anode layer (7), a cathode layer (9), a light emitting layer (8) between the anode and cathode layers, and an intermediate layer (4) between the substrate and the anode layer. An electrically conducting element is embedded in the intermediate layer such that it is in contact with the anode layer. Also, scattering particles for scattering the light are embedded in the intermediate layer, increasing the light outcoupling efficiency of the device. Since the electrically conducting element is embedded in the intermediate layer and not, for instance, on top of the anode layer, i.e. not in between the anode and cathode layers, the sheet resistance of the anode layer can be reduced, without requiring a passivation layer which may adversely affect the light emitting material. Furthermore, the embedded electrically conducting element allows the thickness of the transparent anode layer to be reduced to a thickness of about 50 nm or less, thereby minimizing the influence of light absorption by the transparent anode layer on the light outcoupling efficiency. This allows for an improved light emission quality.

### FIELD OF THE INVENTION

The invention relates to a light emitting device, a layer structure for being used to produce the light emitting device and a production method for producing the layer structure.

### BACKGROUND OF THE INVENTION

An organic light emitting device (OLED) comprises a substrate like a glass substrate with an anode layer, a cathode layer and an organic light emitting layer in between the anode layer and the cathode layer, wherein the organic light emitting layer is adapted to emit light, if voltage is applied to the anode layer and the cathode layer. Moreover, on top of the anode layer, i.e. within the organic light emitting layer, a metallic grid may be provided, in order to reduce the sheet resistance of the anode layer, wherein on top of the metal grid a passivation layer like a photoresist layer can be provided, in order to suppress electrical shorts in the OLED. However, the organic light emitting layer may be adversely affected by humidity and by reactions with passivation material forming the passivation layer, thereby reducing the light emission quality of the OLED.

### SUMMARY OF THE INVENTION

It is an object of the present invention to provide a light emitting device having an improved light emission quality. It is a further object of the present invention to provide a layer structure that can be used to produce the light emitting device, and to provide a production method for producing the layer structure.

In a first aspect of the invention a light emitting device is presented, comprising a substrate, a transparent anode layer, a cathode layer, and a light emitting layer between the anode and cathode layers, wherein the light emitting layer is adapted to emit light if a voltage is applied to the anode and cathode layers. The light emitting device further comprises an intermediate layer between the substrate and the transparent anode layer, wherein the intermediate layer comprises intermediate layer material having a refractive index that is larger than the refractive index of the substrate. Furthermore, an electrically conducting element is embedded in the intermediate layer such that it is in contact with the transparent anode layer. Scattering particles for scattering the light are embedded in the intermediate layer, and the transparent anode layer has a thickness of about 50 nm or less, such as a thickness of 20 nm.

The scattering particles that are embedded in the intermediate layer increase the light outcoupling efficiency of the device. However, if such a scattering function is added to the device, then absorption of light by any of the further layers of the device plays a much bigger role, for example due to scattering processes and increased lengths of light paths, which is especially true for the transparent anode layer.

Since the electrically conducting element is embedded in the intermediate layer and not on top of the anode layer, i.e. not in between the anode and cathode layers, a passivation layer is not needed on the electrically conducting element for suppressing electrical shorts within the light emitting layer, wherein the sheet resistance of the anode layer can still be reduced, because the electrically conducting element is in contact with the anode layer. Also, since a passivation layer in contact with the light emitting layer is not needed, the light emitting layer cannot be adversely affected by humidity or by reactions with a passivation material of the passivation layer, thereby allowing for an improved light emission quality. Moreover, because the sheet resistance of the anode layer is mainly determined by the embedded electrically conducting element, the latter allows the thickness of the transparent anode layer to be reduced to a thickness of about 50 nm or less (such as a thickness of 20 nm), thereby minimizing the influence of light absorption by the transparent anode layer on the light outcoupling efficiency, so that the latter can be increased even further.

The electrically conducting element is preferentially a metal element and the substrate is preferentially a glass or polymer substrate. The intermediate layer is preferentially made of electrically insulating intermediate layer material in which the electrically conducting element is embedded. The cathode layer may be reflecting for the emitted light. The light emitting layer preferentially comprises organic light emitting material such that the light emitting device is preferentially an OLED.

It is preferred that the refractive index of the intermediate layer material is similar, especially equal, to the refractive index of the transparent anode layer. It is also preferred that the refractive index of the intermediate layer material is similar, especially equal, to an average of the refractive indices of the anode layer and the light emitting layer. In a preferred embodiment the refractive index of the intermediate layer material is equal to or larger than 1.7. Moreover, a surface of the substrate facing the intermediate layer may comprise scattering structures. In particular, the surface of the substrate facing the intermediate layer may be roughened for providing scattering structures on the surface. The relatively high refractive index of the intermediate layer and the scattering particles embedded in the intermediate layer and/or the scattering structures on the surface of substrate can improve the efficiency of coupling the light emitted by the light emitting layer through the transparent anode layer, the intermediate layer and the substrate out of the light emitting device.

In an embodiment the electrically conducting element is arranged only in a part of the intermediate layer facing the anode layer. Moreover, the electrically conducting element is preferentially an electrically conducting grid. If the electrically conducting element is an electrically conducting grid, the sheet resistance of the anode layer can relatively homogeneously be reduced, thereby increasing the luminance homogeneity of the light emitting device.

In an embodiment the intermediate layer comprises a first part made by a first intermediate layer material and a second part made by a second intermediate layer material. In particular, the second part may be a part of the intermediate layer facing the anode layer and comprising the electrically conducting element and the first part may be a part of the intermediate layer facing the substrate and not comprising the electrically conducting element. Moreover, the first part may comprise scattering particles for scattering the light, i.e. the scattering particles may only be present in the first part. Using different intermediate layer materials for the first and second parts may be advantageous, when producing the light emitting device. For instance, for producing the second part a second intermediate layer material may be used, which is especially suited for embedding the electrically conducting element, and for producing the first part a first intermediate layer material may be used, which is especially suited for embedding the scattering particles.

In a second aspect of the invention a layer structure is presented, which can be used to produce the light emitting device according to the first aspect of the invention. The layer structure comprises a substrate, an electrode layer which will form the transparent anode layer in the light emitting device, and an intermediate layer between the substrate and the transparent anode layer, wherein the intermediate layer comprises intermediate layer material having a refractive index that is larger than the refractive index of the substrate, wherein an electrically conducting element is embedded in the intermediate layer such that it is in contact with the transparent anode layer, and wherein scattering particles for scattering the light are embedded in the intermediate layer. In order to produce the light emitting device, further layers like the light emitting layer and the cathode layer can be provided on the layer structure.

In a third aspect of the invention a method for producing the layer structure according to the second aspect is presented, wherein the method comprises the steps of providing a substrate, providing an intermediate layer on the substrate, wherein an electrically conducting element is embedded in the intermediate layer, wherein the intermediate layer comprises intermediate layer material having a refractive index that is larger than the refractive index of the substrate, and wherein scattering particles for scattering the light are embedded in the intermediate layer, providing an electrode layer, which will form the transparent anode layer, on the intermediate layer, the transparent anode layer having a thickness of about 50 nm or less, wherein the intermediate layer with the electrically conducting element and the transparent anode layer are provided such that the electrically conducting element is in contact with the transparent anode layer.

For producing the light emitting device according to the first aspect of the invention, the method can further comprise the steps of providing a light emitting layer on the transparent anode layer, and providing a cathode layer on the light emitting layer such that the light emitting layer is arranged between the anode and cathode layers, wherein the light emitting layer is adapted to emit light, if a voltage is applied to the anode and cathode layers.

In an embodiment, the provision of the intermediate layer with the embedded electrically conducting element includes providing the electrically conducting element on the substrate and then depositing the intermediate layer material on the substrate with the electrically conducting element, in order to form the intermediate layer, wherein the production method further includes removing intermediate layer material from the electrically conducting element before providing the transparent anode layer on the intermediate layer. In a further embodiment the provision of the intermediate layer with the embedded electrically conducting element includes providing a preliminary intermediate layer, which does not comprise the electrically conducting element, on the substrate, producing grooves in the preliminary intermediate layer and filling the grooves with electrically conducting material for forming the electrically conducting element. Moreover, the provision of the intermediate layer with the embedded electrically conducting element may include providing intermediate layer material on the substrate, in order to form a first part of the intermediate layer facing the substrate and not including the electrically conducting element, and providing a second part of the intermediate layer with the electrically conducting element on the first part of the intermediate layer.

It shall be understood that the light emitting device according to the first aspect, the layer structure according to the second aspect, and the method according to the third aspect have similar and/or identical preferred embodiments, in particular, as defined in the dependent claims.

It shall be understood that a preferred embodiment of the invention can also be any combination of the dependent claims or above embodiments with the respective independent claim. These and other aspects of the invention will be apparent from and elucidated with reference to the embodiments described hereinafter.

### BRIEF DESCRIPTION OF THE DRAWINGS

In the following drawings:

FIGS. 1 to 4 schematically and exemplary show different embodiments of an OLED,

FIG. 5 shows a flowchart exemplary illustrating an embodiment of a production method for producing an OLED, and

FIG. 6 schematically and exemplary shows an embodiment of a production apparatus for producing an OLED.

### DETAILED DESCRIPTION OF THE EMBODIMENTS

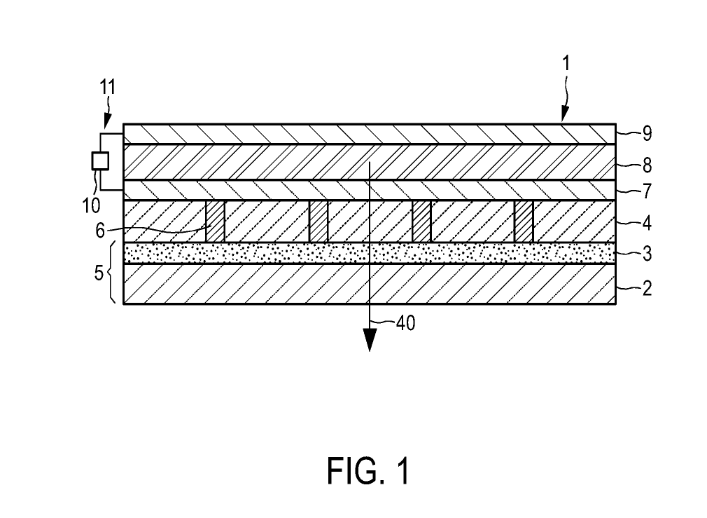

FIG. 1 shows schematically and exemplarily an embodiment of a light emitting device. The light emitting device 1 is an OLED comprising an organic light emitting layer 8 between a first electrode layer being a transparent anode layer 7 and a second electrode layer being a reflective cathode layer 9. A voltage source 10 is connected to the anode layer 7 and the cathode layer 9 via electrical connections 11 like wires, wherein the organic light emitting layer 8 is adapted to emit light 40, if the voltage is applied to the anode layer 7 and the cathode layer 9.

The organic light emitting layer 8 comprises a stack of sublayers including one or several organic light emitting sublayers and optionally further sublayers like one or several hole injection sublayers, one or several hole transport sublayers, one or several electron transport sublayers, one or several charge generation sublayers, et cetera. The OLED 1 further comprises a substrate 5, which might be a glass substrate or a polymer substrate, and an intermediate layer 4 on the substrate 5, wherein the anode layer 7 is arranged on the intermediate layer 4. Thus, the intermediate layer 4 is arranged between the substrate 5 and the anode layer 7. The intermediate layer 4 comprises an electrically conducting element 6 embedded in the intermediate layer 4 such that the electrically conducting element 6 is in contact with the anode layer 7. In this embodiment the electrically conducting element 6 is a metal grid.

The intermediate layer 4, i.e. the intermediate layer material embedding the electrically conducting element 6, has a refractive index being equal to or larger than 1.7, wherein the refractive index relates to the wavelength of the light emitted by the light emitting layer 8. Moreover, this refractive index may be similar to the refractive index of the anode layer 7 and/or to the refractive index of an average of the refractive indices of the anode layer 7 and the light emitting layer 8. The intermediate layer material embedding the electrically conducting element 6, which in this embodiment reaches from the substrate 5 to the anode layer 7, and having this refractive index is preferentially electrically insulating.

The substrate 5 comprises a roughened surface 3 facing the intermediate layer 4, i.e. scattering structures are provided on the surface of the substrate 5. The body 2, i.e. the remaining part of the substrate 5, does not have scattering structures and just allows the light 40 emitted by the light emitting layer 8 to leave the OLED 1.

The substrate 5 with the intermediate layer 4 and the anode layer 7 forms a layer structure, which can be produced firstly without providing also the other layers, wherein later this layer structure can be used for producing the light emitting layer. For instance, the layer structure can be produced at a first production site, whereafter the remaining layers can be provided on the layer structure at a second production site for forming the light emitting device.

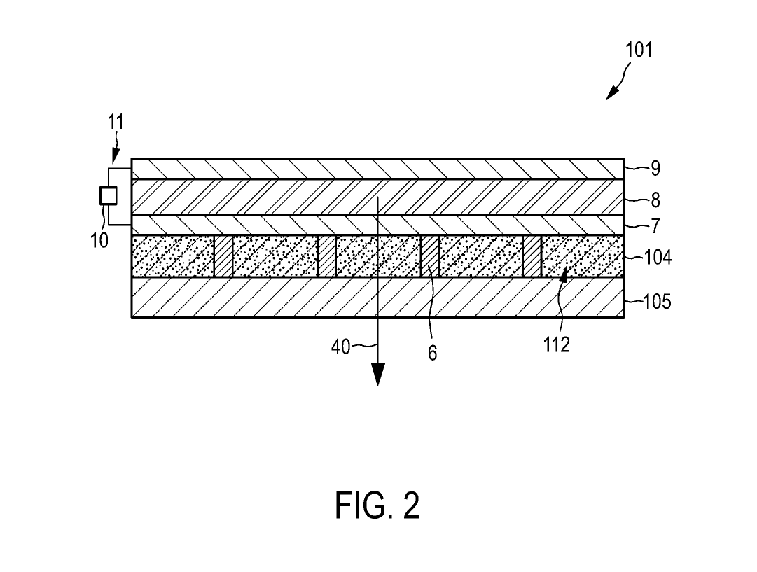

FIG. 2 schematically and exemplarily shows a further embodiment of an OLED. Also in this embodiment the OLED 101 comprises an anode layer 7 and a cathode layer 9 with an intermediate organic light emitting layer 8 between the anode layer 7 and the cathode layer 9. Moreover, also in this embodiment the voltage source 10 is connected to the anode layer 7 and the cathode layer 9, in order to apply voltage to the anode and cathode layers 7, 9, wherein the organic light emitting layer 8 emits light, if the voltage is applied to the anode and cathode layers 7, 9. However, in this embodiment the substrate 105 comprises a smooth surface facing an intermediate layer 104, wherein the intermediate layer 104 is similar to the intermediate layer 4 described above with reference to FIG. 1, but additionally comprises scattering particles 112 for scattering the light 40 while traversing the intermediate layer 104.

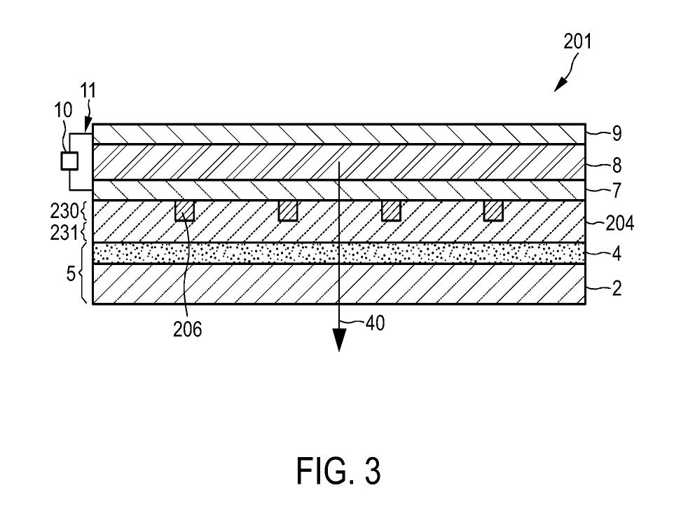

FIG. 3 schematically and exemplarily shows a further embodiment of an OLED. In this embodiment the OLED 201 also comprises an anode layer 7, a cathode layer 9 with an intermediate light emitting layer 8, wherein the anode layer 7 and the cathode layer 9 are electrically connected to a voltage source 10. However, in this embodiment the OLED 201 comprises a substrate 5 with a roughened surface 4 as described above with reference to FIG. 1. Moreover, in this embodiment the electrically conducting element 206 is not arranged in a first part 231 of the intermediate layer 204, which faces the substrate 5, but only in a second part 230 facing the anode layer 7. Thus, the intermediate layer 204 may have a thickness being much larger than what is necessary for reducing the sheet resistance of the anode layer 7 to a desired value. For instance, the intermediate layer 204 may have a thickness of about 10 μm, whereas the metal grid 206 may have a thickness of about 1 μm.

Furthermore, the first and second parts 231, 230 of the intermediate layer 204 may be formed by the same intermediate layer material or by different intermediate layer materials preferentially having the same refractive index. For instance, the first part 231 may be a sol-gel part containing a mixture of SiO₂ and TiO₂ for adjusting the refractive index of the first part 231 as desired. The second part 230 may also be a sol-gel part with the mixture of SiO₂ and TiO₂, or the second part may be formed by another material like a transparent polymer having a desired refractive index.

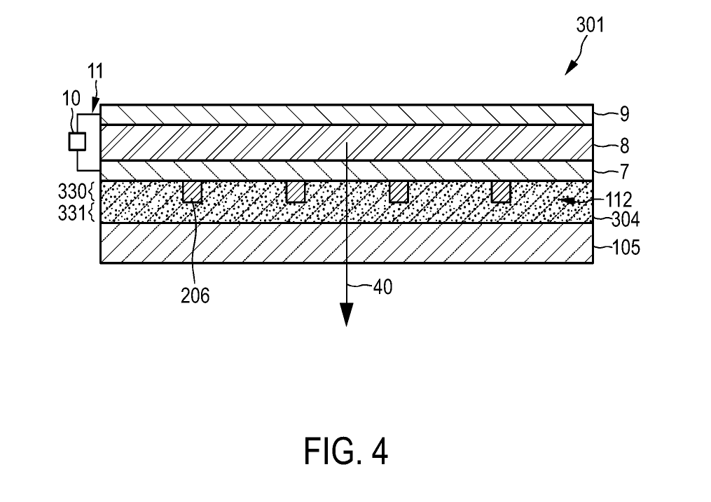

FIG. 4 shows schematically and exemplarily a further embodiment of an OLED. In this embodiment the OLED 301 also comprises an anode layer 7, a cathode layer 9 and a light emitting layer 8 arranged between the anode layer 7 and the cathode layer 9. Moreover, also in this embodiment the anode layer 7 and the cathode layer 9 are electrically connected to a voltage source 10 via electrical connectors 11. However, in this embodiment the substrate 105 comprises a smooth surface facing the intermediate layer 304 and the intermediate layer 304 comprises the electrically conducting element 206 not in a first part 331 facing the substrate 105, but only in a second part 330 facing the anode layer 7. Furthermore, the intermediate layer 304 comprises scattering particles 112. It should be noted that FIG. 4 and also FIGS. 1 to 3 are not to scale.

Also in this embodiment the intermediate layer 304 may have a thickness being much larger than what is necessary for reducing the sheet resistance of the anode layer 7 to a desired value. For instance, the intermediate layer 304 may have a thickness of about 10 μm, whereas the metal grid 306 may have a thickness of about 1 μm. Furthermore, also in this embodiment the first and second parts 331, 330 of the intermediate layer 304 may be formed by the same intermediate layer material or by different intermediate layer materials preferentially having the same refractive index. In an embodiment the scattering particles 112 may not be present in the entire intermediate layer 304, but only in the first part 331. The first part 331 may be a sol-gel part containing a mixture of SiO₂ and TiO₂ for adjusting the refractive index of the first part 331 as desired, wherein in this embodiment the sol-gel part further comprises the scattering particles. The second part 330 may also be a sol-gel part with the mixture of SiO₂ and TiO₂, with or without the scattering particles, or the second part 330 may be formed by another material like a transparent polymer having a desired refractive index. The first part 331 may also be formed by glass having a scattering function. For instance, glass powder may be provided on the substrate and subsequently fired for creating a coating forming the first part. This may be performed as described in US 2009/0153972 A1, which is herewith incorporated by reference.

The scattering particles 112 preferentially have a refractive index significantly different from the refractive index of the intermediate layer 304. Preferentially, the difference between the refractive index of the scattering particles 112 and the refractive index of the intermediate layer 304 is equal to or larger than 0.3. The size of the scattering particles is preferentially in the range of 200 nm to 5000 nm and the volume fraction is preferentially between 0.5 and 15 percent.

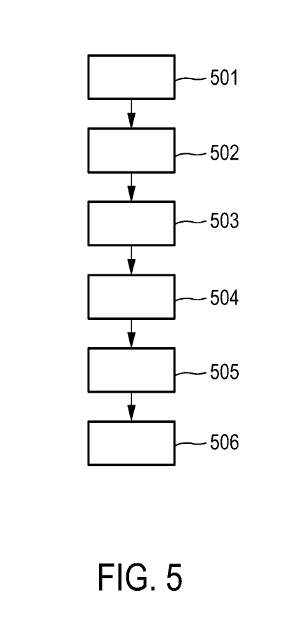

In the following an embodiment of a production method for producing a light emitting device will exemplarily be described with reference to a flowchart shown in FIG. 5.

In step 501 a substrate is provided. For instance, a smooth transparent glass or polymer plate 105 or a glass or polymer plate with a roughened surface 5 may be provided. The surface may be roughened by using sand blasting or by using another roughening technique. In step 502 an intermediate layer is provided on the substrate, wherein an electrically conducting element like a metal grid is embedded in the intermediate layer and wherein the intermediate layer comprises a refractive index being larger than the refractive index of the substrate. For instance, the electrically conducting element can be provided on the substrate and then intermediate layer material can be deposited on the substrate with the electrically conducting element, in order to form the intermediate layer, wherein in this case the production method may further include removing intermediate layer material from the electrically conducting element before providing a first electrode layer on the intermediate layer. The electrically conducting element, which can be a metal grid, may be provided on the substrate by, for instance, screen printing, inkjet printing, gravure printing, flexo- or tampo-printing, sputtering/photolithography, plating, et cetera. If sputtering/photolithography is used, the complete substrate or at least a complete area on the substrate, where the electrically conducting element should be provided, may be coated with electrically conducting material by sputtering, whereupon the electrically conducting element may be patterned by photolithography. Alternatively a mask may be printed on the substrate, whereupon the electrically conducting material may be sputtered on top of the mask, wherein then the mask may be removed leaving the patterned electrically conducting element, especially the metal grid, on the substrate.

The intermediate layer material, which may be regarded as being a high-n layer material, can be deposited on the substrate with the electrically conducting element by slit coating, slot die coating, spin coating, screen printing, inkjet printing, dip coating, spray coating, in particular, plasma spray coating, chemical vapor deposition (CVD), sputtering or any other known deposition technique. The removing of the intermediate layer material from the electrically conducting element may be performed by polishing or any other technique for removing the intermediate layer material from the electrically conducting element, until the electrically conducting element, in particular, the metal grid, is not covered by the intermediate layer material any more. The intermediate layer material may be either an organic material or an inorganic material having the desired refractive index. In an embodiment the intermediate layer material is SiN.

As an alternative to firstly providing the electrically conducting element on the substrate, then depositing the intermediate layer material on the substrate with the electrically conducting element and finally removing intermediate layer material from the electrically conducting element, in step 502 the intermediate layer with the embedded electrically conducting element may be provided by providing a preliminary intermediate layer, which does not comprise the electrically conducting element, on the substrate, by producing grooves in the preliminary intermediate layer and filling the grooves with electrically conducting material for forming the electrically conducting element within the intermediate layer. After the grooves have been filled by the electrically conducting material, optionally the resulting surface may be smoothed by, for instance, polishing or any other smoothing technique, before providing a further layer on this surface. The grooves may be cut into the intermediate layer by, for instance, laser ablation, sawing, etching, et cetera.

Moreover, in step 502 firstly intermediate layer material may be provided on the substrate, without embedding the electrically conducting element, in order to form a first part of the intermediate layer facing the substrate, which does not include the electrically conducting element, wherein then a second part of the intermediate layer can be provided, which includes the electrically conducting element, on the first part of the intermediate layer. The second part of the intermediate layer with the electrically conducting element can be produced as described above, i.e., for instance, by firstly providing the electrically conducting element on the substrate and then depositing the intermediate layer material on the substrate with the electrically conducting element, wherein then intermediate layer material is removed from the electrically conducting element before providing a first electrode layer on the intermediate layer, or by firstly providing a preliminary intermediate layer, which does not comprise the electrically conducting element, on the substrate, by producing grooves in the preliminary intermediate layer and by filling the grooves with electrically conducting material for forming the electrically conducting element.

In step 503 a first electrode layer is provided on the intermediate layer, wherein the intermediate layer with the electrically conducting element and the first electrode layer are provided such that the electrically conducting element is in contact with the first electrode layer. In this embodiment the first electrode layer is an inorganic or organic transparent anode layer made of, for instance, ITO (indium tin oxide), IZO (indium zinc oxide), AZO (aluminum zinc oxide), GZO (gallium zinc oxide), PEDOT:PSS (poly(3,4-ethylenedioxythiophene) poly(styrenesulfonate)) or another transparent inorganic or organic conducting material. For depositing the anode layer sputtering, ion plating, CVD, especially low pressure CVD, atmospheric pressure CVD or plasma enhanced CVD, a sol-gel process, et cetera may be used. If the first electrode layer comprises organic conductive material, the organic conductive material is preferentially deposited by spin coating, slit coating, slot die coating, et cetera.

In step 504 a light emitting layer is provided on the intermediate layer. In this embodiment an organic light emitting layer is provided on the intermediate layer, wherein in step 505 a second electrode layer is provided on the light emitting layer such that the light emitting layer is arranged between the first and second electrode layers. The light emitting layer is adapted to emit light, if voltage is applied to the first and second electrode layers. The second electrode layer is preferentially a cathode layer, which may be reflective for the light emitted by the light emitting layer.

In step 506 the first and second electrode layers are electrically connected to a voltage source via electrical conductors, in order to allow the light emitting device to emit light, if voltage is applied to the first and second electrode layers. The production method can comprise further steps for, for instance, adding further components to the light emitting device like an encapsulation and/or for processing the components of the light emitting device. Steps 501 to 503 can be regarded as being steps of a production method for producing a layer structure comprising the substrate, the intermediate layer with the embedded electrically conducting element and the first electrode layer.

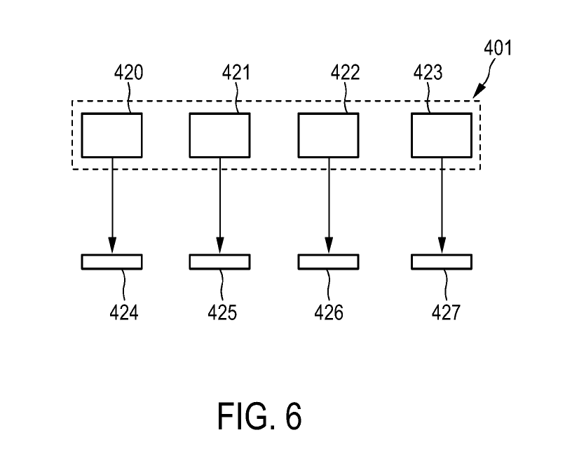

The steps of the production method may be performed manually, semi-automatically or fully automatically. For producing the light emitting device a production apparatus may be used as schematically and exemplarily shown in FIG. 6.

The production apparatus 401 comprises an intermediate layer providing unit 420 for providing an intermediate layer on a provided substrate 424, wherein an electrically conducting element is embedded in the intermediate layer and wherein the intermediate layer comprises a refractive index being larger than the refractive index of the substrate. The intermediate layer providing unit 420 can be adapted to perform the part of the production method described above with reference to step 502. The production apparatus 401 can further comprise a first electrode layer providing unit 421 for providing a first electrode layer on the substrate with the intermediate layer 425, wherein the intermediate layer with the electrically conducting element and the first electrode layer are provided such that the electrically conducting element is in contact with the first electrode layer. This leads to an intermediate product 426. The first electrode layer providing unit 421 may be adapted to perform the production step 503 described above with reference to FIG. 5. A light emitting layer providing unit 422 provides a light emitting layer on the first electrode layer, in particular, in accordance with above described production step 504, thereby forming a further intermediate product 427, and a second electrode layer providing unit 423 may be adapted to provide a second electrode layer on the light emitting layer such that the light emitting layer is arranged between the first and second electrode layers, wherein the light emitting layer is adapted to emit light, if voltage is applied to the first and second electrode layers. The second electrode layer providing unit 423 may be adapted to provide the second electrode layer in accordance with above described production step 505. The production apparatus 401 may comprise further units for performing further production steps. For instance, the production apparatus can comprise a further unit for electrically connecting the first and second electrode layers to a voltage source or a further unit for providing an encapsulation.

The intermediate layer providing unit 420 and the first electrode layer providing unit 421 can be regarded as forming a production apparatus for producing a layer structure comprising the substrate, the intermediate layer with the embedded electrically conducting element and the first electrode layer.

The produced OLED device preferentially comprises a metal grid embedded in the high-n layer, i.e. in the intermediate layer, used for light outcoupling, instead of using a metal grid placed on top of the anode layer. The metal grid embedded in the high-n layer does not need passivation and it enables to provide a flat surface, on which other layers of the OLED may be deposited, which is advantageous for the reliability of the OLED. If the thickness of the grid is relatively thin, i.e. relative to the thickness of the high-n layer, it is possible to add an additional high-n layer coating step at the beginning of the production of the high-n layer such that the metal grid has finally no contact with the substrate, but instead is only embedded in an upper region of the high-n layer.

Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality.

A single unit or device may fulfill the functions of several items recited in the claims. The mere fact that certain measures are recited in mutually different dependent claims does not indicate that a combination of these measures cannot be used to advantage.

Procedures like the provision of an intermediate layer on a substrate wherein an electrically conducting element is embedded in the immediate layer, providing a first electrode layer, providing a light emitting layer, providing a second electrode layer et cetera performed by one or several units or devices can be performed by any other number of units or devices. For example, steps 502 to 505 can be performed by a single unit or by any other number of different units. These procedures and the control of the production apparatus in accordance with the production method can be implemented as program code means of a computer program and as dedicated hardware.

A computer program may be stored and/or distributed on a suitable medium, such as an optical storage medium or a solid-state medium, supplied together with or as part of other hardware, but may also be distributed in other forms, such as via the Internet or other wired or wireless telecommunication systems.

Any reference signs in the claims should not be construed as limiting the scope.

The invention relates to a light emitting device comprising a substrate, first and second electrode layers, a light emitting layer between the first and second electrode layers, and an intermediate layer between the substrate and the first electrode layer. An electrically conducting element is embedded in the intermediate layer such that it is in contact with the first electrode layer. Since the electrically conducting element is embedded in the intermediate layer and not, for instance, on top of the first electrode layer, i.e. not in between the first and second electrode layers, the sheet resistance of the first electrode layer can be reduced, without requiring a passivation layer which may adversely affect the light emitting material. This allows for an improved light emission quality.

1. A light emitting device comprising:
a substrate,
an intermediate layer provided on the substrate,
a transparent anode layer, provided on the intermediate layer,
a light emitting layer between the anode and cathode layers for emitting light when a voltage is applied to the anode and cathode layers, where the light is emitted from the light emitting device through the substrate, a reflective cathode layer, and
wherein the intermediate layer between the substrate and the transparent anode layer comprises intermediate layer material which has a refractive index that is larger than the refractive index of the substrate,
wherein an electrically conducting element is embedded in the intermediate layer such that it is in contact with the transparent anode layer,
wherein scattering particles for scattering the light are embedded in the intermediate layer, and
wherein the transparent anode layer (7) has a thickness of 50 nm or less.

2. The light emitting device according to claim 1, wherein the refractive index of the intermediate layer material is equal to the refractive index of the transparent anode layer and/or to an average of the refractive indices of the transparent anode layer and the light emitting layer.

3. The light emitting device according to claim 1, wherein the refractive index of the intermediate layer material is equal to or larger than 1.7.

4. The light emitting device according to claim 1, wherein the intermediate layer material is electrically insulating intermediate layer material in which the electrically conducting element is embedded.

5. The light emitting device according to claim 1, wherein a surface of the substrate facing the intermediate layer comprises scattering structures.

6. The light emitting device according to claim 1, wherein the electrically conducting element is arranged only in a part of the intermediate layer facing the transparent anode layer.

7. The light emitting device according to claim 1, wherein the intermediate layer comprises a first part made by a first intermediate layer material and a second part made by a second intermediate layer material.

8. (canceled)

9. A method for producing the layer structure according to claim 1, wherein the method comprises the steps of:
providing a substrate,
providing an intermediate layer on the substrate, wherein an electrically conducting element is embedded in the intermediate layer, wherein the intermediate layer comprises intermediate layer material having a refractive index that is larger than the refractive index of the substrate, and wherein scattering particles for scattering the light are embedded in the intermediate layer,
providing a transparent anode layer on the intermediate layer, the transparent anode layer having a thickness of 50 nm or less, wherein the intermediate layer with the electrically conducting element and the transparent anode layer are provided such that the electrically conducting element is in contact with the transparent anode layer.

10. The method according to claim 9, wherein the provision of the intermediate layer with the embedded electrically conducting element includes providing the electrically conducting element on the substrate and then depositing the intermediate layer material on the substrate with the electrically conducting element, in order to form the intermediate layer, wherein the production method further includes removing intermediate layer material from the electrically conducting element before providing the transparent anode layer on the intermediate layer.

11. The method according to claim 9, wherein the provision of the intermediate layer with the embedded electrically conducting element includes providing a preliminary intermediate layer, which does not comprise the electrically conducting element, on the substrate, producing grooves in the preliminary intermediate layer and filling the grooves with electrically conducting material for forming the electrically conducting element.

12. The method according to claim 9, wherein the provision of the intermediate layer with the embedded electrically conducting element includes providing intermediate layer material on the substrate, in order to form a first part of the intermediate layer facing the substrate and not including the electrically conducting element, and providing a second part of the intermediate layer with the electrically conducting element on the first part of the intermediate layer.
